(19) United States
(12) Patent Application Publication
(10) Pub. No.: US 2008/0166891 A1
(43) Pub. Date: Jul. 10, 2008

(54) HEAT TREATMENT METHOD FOR SILICON WAFER

(75) Inventors: Manabu Hirasawa, Kitakanbara-gun (JP); Koji Izunome, Kitakanbara-gun (JP); Koji Araki, Kitakanbara-gun (JP); Tatsuhiko Aoki, Kitakanbara-gun (JP)

Correspondence Address: FOLEY AND LARDNER LLP;SUITE 500, 3000 K STREET NW, WASHINGTON, DC, 20007, US

(73) Assignee: COVALENT MATERIALS CORPORATION

(21) Appl. No.: 11/965,214

(22) Filed: Dec. 27, 2007

(30) Foreign Application Priority Data
Dec. 28, 2006 (JP) 2006-355590
Dec. 11, 2007 (JP) 2007-319744

(51) Int. Cl. H01L 21/00

(52) U.S. Cl. 438/795; 257/E21.324

(57) ABSTRACT

The present invention provides a heat treatment method for a silicon wafer in which, with respect to a surface of the silicon wafer made flat at an atomic level by a high-temperature heat-treatment at 1,100° C. or more, a surface roughness of the wafer can be reduced compared with the conventional one while maintaining a step terrace structure on the surface of the above-mentioned wafer, and the surface of such a wafer can be formed stably. In the heat treatment method for the silicon wafer in which the step terrace structure is formed on the surface of the silicon wafer, after the silicon wafer is heat treated at 1,100° C. or more in a heat treatment furnace in a reducing gas or inert gas atmosphere, the atmosphere in the furnace is arranged to be of argon gas at a temperature of 500° C. or more in the furnace when reducing the temperature and argon gas continues to be introduced into the furnace until the silicon wafer is removed from the furnace, so that the step terrace structure on the surface of the above-mentioned silicon wafer may be maintained and a root mean square roughness Rms per 3 μm×3 μm may be 0.06 nm or less.

### BACKGROUND OF THE INVENTION

1. Field of the Invention

The present invention relates to a heat treatment method for obtaining a silicon wafer whose surface is atomically flat in a high-temperature heat-treatment for a silicon wafer.

2. Description of the Related Art

In a process of manufacturing a silicon wafer from a silicon single crystal ingot pulled up by the Czochralski (CZ) method, a heat treatment is carried out at 1,100° C. or more for the purpose of reducing crystal defects at a surface of the wafer, improving a surface roughness (micro roughness), etc.

For example, Japanese Patent No. 3292545 (patent document 1) discloses a heat treatment method in which the silicon wafer is subjected to a high-temperature heat-treatment at 1,100° C. or more for a predetermined period of time in a reducing gas or inert gas atmosphere, then the temperature is reduced to 850° C. or less to replace the above-mentioned atmosphere with a nitrogen gas. According to such a heat treatment method, it is supposed that a nitride film is formed on the surface of the wafer, to thereby inhibit generation of a defect of an oxide film resulting from the wafer without increasing the surface roughness of the wafer.

Silicon atoms of the surface of the silicon wafer are re-arranged for stabilization by the high-temperature heat-treatment at 1,100° C. or more in the reducing gas or inert gas atmosphere, so that the surface of the wafer is arranged to be flat to the extent of an atomic level. In the above-mentioned re-arrangement, a step terrace structure having a step at the atomic level of approximately 1-2 atomic layers on the surface is formed on the surface of the wafer.

As for a fine surface roughness (micro roughness) measured by an atomic force microscope (AFM) after polishing and processing the silicon wafer which is not subjected to the heat treatment, Rms (root mean square roughness) per 3 μm×3 μm is 0.15-0.2 nm. While, Rms measured by AFM of the surface of the silicon wafer made flat as mentioned above is approximately 0.1 nm.

Accordingly it can be seen that such a heat treatment, as described above, reduces the surface roughness.

A terrace width of the above-mentioned step terrace structure increases with decreasing OFF angle of a silicon crystal surface, and a clearer step terrace structure is observed in the AFM observation after the heat treatment.

For example, Japanese Patent Publication (KOKAI) No. H8-264401 (patent document 2) discloses that a single crystal silicon wafer of a surface orientation (100) is inclined and sliced at an angle of 0.01-0.2° in a perpendicular line <110> direction of a (001) plane, and subjected to a cleaning process, then to a heat-treatment at 600-1,300° C. in an argon atmosphere, so that a step terrace structure can be formed.

However, in such a heat treatment as described above, it is found that the surface roughness of the silicon wafer after the heat treatment changes with the atmosphere. For example, Rms per 3 μm×3 μm is approximately 0.07 nm in the case where after the silicon wafer is heat treated in the argon gas atmosphere, the temperature is reduced to 700° C., then argon is replaced with nitrogen and the silicon wafer is removed from a furnace in a nitrogen atmosphere. On the other hand, Rms is approximately 0.1 nm in the case where after the silicon wafer is heat treated in a hydrogen gas atmosphere, the temperature is reduced to 700° C., then hydrogen is replaced with nitrogen and the silicon wafer is removed from the furnace in a nitrogen gas atmosphere.

As a result of considering the cause of difference in surface roughness as described above, the present inventors have found that this is not influenced by the gas atmosphere at the time of high-temperature heat-treatment at 1,100° C. or more, but influenced by the gas atmosphere replaced at the time of reducing the temperature after the above-mentioned high temperature treatment or after reducing the temperature.

### SUMMARY OF THE INVENTION

Based on the above-mentioned consideration result, the present invention adds further improvement to the method and aims to provide a heat-treatment method for a silicon wafer in which, with respect to a surface of the silicon wafer made flat at an atomic level by a high-temperature heat-treatment at a high temperature of 1,100° C. or more, after the high-temperature heat-treatment, an atmosphere in a furnace is held properly at a temperature reducing stage until the silicon wafer is removed from the furnace, whereby a surface roughness (micro roughness) of the wafer is more reduced than that of conventional one, and the surface of such a wafer can be formed stably, while maintaining a step terrace structure of the surface of the above-mentioned wafer.

The heat treatment method for the silicon wafer in accordance with the present invention is a heat treatment method for a silicon wafer in which a step terrace structure is formed on a surface of the silicon wafer wherein after the silicon wafer is heat treated at 1,100° C. or more in a heat treatment furnace of a reducing gas or inert gas atmosphere, the furnace atmosphere is arranged to be of argon gas at a temperature of 500° C. or more in the furnace when reducing the temperature and introduction of argon gas into the furnace is continued until the silicon wafer is removed from the furnace, so that the step terrace structure on the surface of the above-mentioned silicon wafer is maintained and a root mean square roughness Rms per 3 μm×3 μm is 0.06 nm or less.

Thus, with respect to the surface of the silicon wafer made flat at the atomic level by the high-temperature heat-treatment at a high temperature of 1,100° C. or more, the furnace atmosphere from a temperature reducing stage after the high-temperature heat-treatment to the removal of the silicon wafer from the furnace is arranged to be of argon gas, so that the surface roughness of the wafer can be reduced compared with that of a conventional one, while maintaining the step terrace structure on the surface of the above-mentioned wafer.

In the above-mentioned heat treatment method, it is preferable to continue to introduce argon gas into the furnace until the whole wafer-placing unit of a wafer boat having thereon at least the above-mentioned silicon wafer comes out of the furnace.

During the temperature reducing stage starting with 500° C. until the silicon wafer is removed from the furnace, the silicon wafer surface is held so as to be enclosed with argon gas, whereby the high flatness can be maintained without damaging the step terrace structure on the surface of the silicon wafer.

Further, when removing the above-mentioned wafer boat from the furnace, it is preferable that the whole wafer boat is surrounded by argon gas which flows from the inside of the furnace.

In this way, it is possible to further exert the effect of maintaining the flatness of the surface of the above-mentioned silicon wafer.

Furthermore, in the case where the above-mentioned wafer boat is removed from a furnace bottom, it is preferable that a flow velocity of argon gas flowing out of an opening of the furnace bottom is between 0.0192 m/s and 0.190 m/s (inclusive).

It is preferable that the gas flow velocity is within the above-mentioned range in terms of protecting, with argon gas, the surface of the silicon wafer removed from the furnace.

As described above, according to the present invention, with respect to the surface of the silicon wafer made flat at the atomic level by the high-temperature heat-treatment at 1,100° C. or more, only by replacing the atmosphere in the furnace in the temperature reducing stage after the high-temperature heat-treatment, the step terrace structure on the surface of the wafer can sufficiently be maintained after removal of the wafer from the furnace. As a result the surface roughness of the wafer can be reduced compared with the conventional one and the surface of such a wafer can be formed stably.

### BRIEF DESCRIPTION OF THE DRAWINGS

FIG. 1 is an AFM image photograph of a surface (3 μm×3 μm) of a silicon wafer in accordance with Example 1.

FIG. 2 is an AFM image photograph of the surface (3 μm×3 μm) of the silicon wafer in accordance with Example 2.

FIG. 3 is an AFM image photograph of the surface (3 μm×3 μm) of the silicon wafer in accordance with Comparative Example 1.

FIG. 4 is an AFM image photograph of the surface (3 μm×3 μm) of the silicon wafer in accordance with Example 3.

FIG. 5 is an AFM image photograph of the surface (3 μm×3 μm) of the silicon wafer in accordance with Example 4.

FIG. 6 is an AFM image photograph of the surface (3 μm×3 μm) of the silicon wafer in accordance with Comparative Example 2.

FIG. 7 is an AFM image photograph of the surface (3 μm×3 μm) of the silicon wafer in accordance with Comparative Example 3.

FIG. 8 is a graph of each surface roughness Rms in a respective one of the AFM image photographs in FIGS. 4-7.

FIG. 9 is a flow chart for explaining a heat treatment process in Example.

FIG. 10 is a graph showing a relationship between the surface roughness of an outflow gas flow velocity at an opening of a furnace bottom and a surface roughness of the silicon wafer in the case where an atmosphere in a furnace is of argon gas (Example 5) or of nitrogen gas (Comparative Example 4) when the silicon wafer is removed from the furnace.

### DESCRIPTION OF THE PREFERRED EMBODIMENTS

Hereafter, the present invention will be described in detail.

In a heat treatment method for a silicon wafer in accordance with the present invention, firstly the silicon wafer is heat treated at 1,100° C. or more in a heat treatment furnace in an atmosphere of a reducing gas or an inert gas. At the time of reducing the temperature after the above-mentioned high-temperature heat-treatment process, the atmosphere in the furnace is of argon gas at 500° C. or more in the furnace. Further, argon gas continues to be introduced into the furnace until the silicon wafer is removed from the furnace.

The present invention is characterized in that, by way of such a heat treatment process, a step terrace structure on the surface of the silicon wafer is maintained and Rms per 3 μm×3 μm is arranged to be 0.06 nm or less.

In other words, the present invention is based on the finding that the replacement of the atmosphere in the furnace at such a predetermined temperature reducing stage reduces the surface roughness of the silicon wafer and is an efficient means for stably forming the surface which is made more atomically flat.

The silicon wafer to be heat treated in the present invention is not particularly limited but may be any one of a silicon wafer substrate obtained in such a way that a silicon single crystal obtained by, for example, the Czochralski (CZ) method, the floating zone (FZ) method, etc. is sliced and then subjected to a mirror surface process, an epitaxial wafer, a SOI wafer, etc.

As described above, in the high-temperature heat-treatment process in accordance with the present invention, the silicon wafer is heat treated at 1,100° C. or more in the atmosphere of the reducing gas or inert gas.

Such a high-temperature heat-treatment is a process which is carried out in an effort to reduce crystal defects at the surface of the silicon wafer, and improve the surface roughness, etc., aiming to form the atomic step terrace structure.

In the above-mentioned heat treatment, in order to keep the silicon wafer clean, the atmosphere is arranged to be of the reducing gas or inert gas. As examples of the reducing gas there may be mentioned hydrogen, ammonia, etc. As examples of the inert gas there may be mentioned helium, neon, argon, etc. These gases can be used either alone or as a mixed gas of two or more gases. Usually, hydrogen gas or argon gas is used.

In addition, in terms of keeping the silicon wafer clean before the above-mentioned high-temperature heat-treatment, it is preferable that the silicon wafer is held in the atmosphere of the inert gas.

Further, it is preferable that the above-mentioned heat treatment temperature is a high temperature in terms of reducing the crystal defects of the wafer, improving the surface roughness, etc. It is also preferable that the treatment is carried out at a high temperature of 1,100° C. or more as described above. It is preferable that time for this high-temperature heat-treatment is approximately 0.5-24 hours.

In the heat treatment method in accordance with the present invention, the atmosphere in the furnace is changed from the reducing gas or inert gas to argon gas at a temperature of 500° C. or more in the furnace when reducing the temperature after the above-mentioned high-temperature heat-treatment process.

By changing to argon gas, a conventional problem that the flatness is deteriorated at the time of reducing the temperature is solved.

In this case, the atmosphere as it is may only be maintained in the temperature reducing process when the atmosphere of the high-temperature heat-treatment is of argon gas.

In addition, although the atmosphere of 100% argon gas is most preferable, it is possible to introduce another type of gas other than little argon gas in order to acquire other effects at the time of the heat treatment.

The temperature at which it is replaced with argon gas after the above-mentioned high-temperature heat-treatment is arranged to be 500° C. or more.

When the temperature at the time of the above-mentioned replacement is less than 500° C., it is difficult to make the surface atomically flat.

Therefore, it is preferable to replace the atmosphere with argon gas at the temperature of 500° C. or more, to thereby further reduce deterioration of the surface roughness of the wafer which is made flat at the atomic level by the above-mentioned high-temperature heat-treatment.

The atmosphere in the furnace is arranged to be of argon gas, then the silicon wafer after the above heat treatment is removed from the furnace after the temperature is reduced to that at which the wafer can be removed from the furnace. It is, however, preferable to continue introducing argon gas into the furnace until the removal is completed.

In the case where the above-mentioned silicon wafer is placed on the wafer boat, it is preferable to continue introducing argon gas into the furnace until the whole wafer-placing unit of the above-mentioned wafer boat comes out of the furnace at least.

Thus, during the temperature reduction starting with 500° C. until the silicon wafer is removed from the furnace, the silicon wafer surface is held so as to be enclosed with argon gas, whereby the high flatness can be maintained without damaging the step terrace structure which is formed on the surface of the silicon wafer at the time of the above-mentioned high-temperature heat treatment.

Further, when removing the above-mentioned wafer boat from the furnace, it is preferable that the whole wafer boat is surrounded by argon gas which flows from the inside of the furnace.

Argon gas is likely to surround the silicon wafer compared with other gases. By continuing introducing argon gas into the furnace until the above-mentioned wafer boat comes out of the opening of the furnace, it remains so that the surface of the silicon wafer may be covered for a while after the silicon wafer is removed from the furnace.

For this reason, by continuing introducing argon gas into the furnace until the above-mentioned wafer boat comes out of the furnace completely, the whole wafer boat can be surrounded by argon gas which flows from the inside of the furnace and it is possible to exert the effect of maintaining the flatness of the surface of the above-mentioned silicon wafer.

In the case where the above-mentioned wafer boat is removed from the furnace bottom, it is preferable that the flow velocity of argon gas which flows out of the opening of the furnace bottom is between 0.0192 m/s and 0.190 m/s (inclusive).

The gas flow velocity within such a range is suitable for protecting the surface of the silicon wafer removed from the furnace by argon gas.

If the above-mentioned gas flow velocity is less than 0.0192 m/s, sufficient protection effects on the surface of the silicon wafer cannot be obtained with argon gas. Most preferably, the gas flow velocity is 0.05 m/s or more.

On the other hand, if the above-mentioned gas flow velocity exceeds 0.190 m/s, it is not found that the high gas flow velocity provides further effect, and there is a possibility of dusting in the furnace.

Although the present invention will be described more particularly with reference to Examples hereafter, the present invention is not limited to the following Examples.

### Example 1

Firstly, a silicon wafer obtained by slicing a silicon (100) crystal ingot having a diameter of 8 inches at 0.03° of OFF angles in the <100> direction was subjected to a mirror surface process.

This silicon wafer was placed on a wafer boat, which was installed in a heat treatment furnace in an argon gas atmosphere. The inside of the furnace was changed from the argon gas atmosphere to the hydrogen gas atmosphere at 700° C., and the temperature was increased and maintained at 1,100° C. for 1 hour to carry out a heat treatment.

Then, the temperature was reduced and the hydrogen gas atmosphere inside the furnace was replaced with the argon gas atmosphere at 700° C., subsequently the temperature was further reduced. Argon gas continued to be introduced into the furnace until the silicon wafer was removed from the furnace.

When removing the wafer boat having thereon the silicon wafer through an opening of a furnace bottom, the silicon wafer was removed from the furnace so that a flow velocity of argon gas between the above-mentioned opening and the wafer boat was 0.1 m/s.

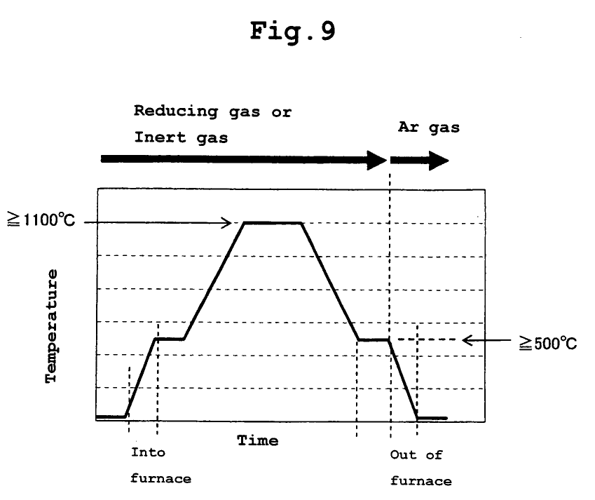

For reference purposes, FIG. 9 shows in flow chart a state of the atmosphere gases and the temperatures in the above-mentioned heat treatment process.

With respect to the surface of the silicon wafer after the heat treatment, a surface concavo-convex image and the surface roughness Rms of a 3 μm×3 μm area were measured by means of AFM.

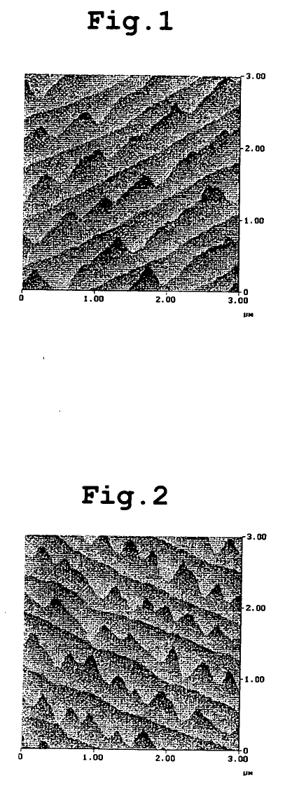

FIG. 1 shows the surface unevenness image of the silicon wafer by AFM observation.

### Example 2

The silicon wafer was heat treated under the same conditions as were described in Example 1, except that the heat treatment temperature of 1,100° C. was changed to 1200° C.

With respect to the surface of the silicon wafer after the heat treatment, the surface concavo-convex image and the surface roughness Rms of the 3 μm×3 μm area were measured by means of AFM.

The surface unevenness image of the silicon wafer by AFM observation is shown in FIG. 2.

### Comparative Example 1

The silicon wafer was heat treated under the same conditions as were described in Example 1, except that the heat treatment temperature of 1,100° C. was changed to 1000° C.

With respect to the surface of the silicon wafer after the heat treatment, the surface concavo-convex image and the surface roughness Rms of the 3 μm×3 μm area were measured by means of AFM.

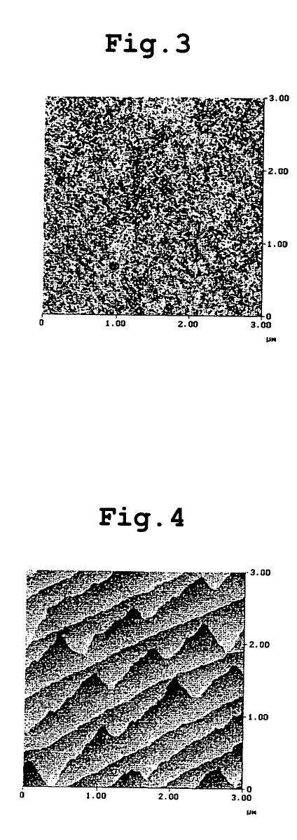

The surface unevenness image of the silicon wafer by AFM observation is shown in FIG. 3.

From the photographs of FIGS. 1-3, in the case where the heat treatment temperature was 1000° C. (Comparative Example 1), a step terrace structure was not formed on the silicon wafer surface. However, in the case where the heat treatment temperature was 1,100° C. or 1200° C. (Examples 1 and 2), step terrace structures were observed clearly.

While the surface roughness Rms was 0.158 nm in the case where the heat treatment temperature was 1000° C. (Comparative Example 1), it was 0.047 nm in the case of 1,100° C. (Example 1), and it was 0.049 nm in the case of 1200° C. (Example 2). Thus it was found that the surface roughness decreased in the case of 1,100° C. or more.

In addition, in the photograph of FIG. 2 a step line of the step terrace structure rises upwardly to the right in the case where the heat treatment temperature is 1,100° C. (Example 1). On the other hand, in the photograph of FIG. 3, the step line of the step terrace structure rises upwardly to the left in the case where the heat treatment temperature is 1200° C. (Example 2). This is because the direction in which the OFF angle was inclined was slightly different depending on the wafer.

### Example 3

With respect to the surface of the silicon wafer as heat treated similarly to Example 2, the surface concavo-convex image and the surface roughness Rms of the 3 μm×3 μm area were measured by means of AFM.

FIG. 4 shows the surface unevenness image of the silicon wafer by AFM observation.

In addition, it appears that a difference between the result and Example 2 may only depend on an individual specificity of the wafer.

### Example 4

The heat treatment was carried out under the same conditions as were described in Example 3 except that the atmosphere was always of argon gas.

With respect to the surface of the silicon wafer after the heat treatment, the surface concavo-convex image and the surface roughness Rms of the 3 μm×3 μm area were measured by means of AFM.

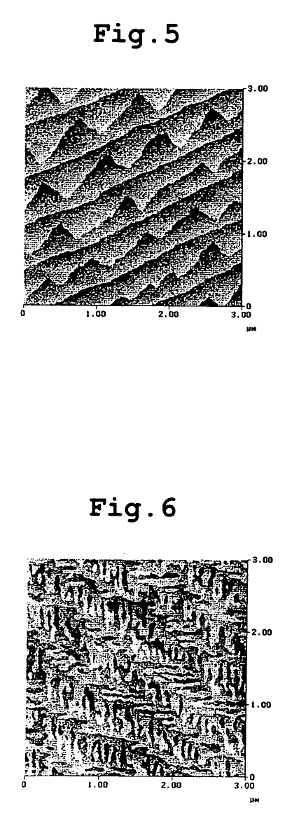

FIG. 5 shows the surface unevenness image of the silicon wafer by AFM observation.

### Comparative Example 2

The inside of the furnace was changed from the nitrogen gas atmosphere to the hydrogen gas atmosphere and the heat treatment was carried out at 700° C. before raising the temperature. The inside of the furnace was changed from the hydrogen gas atmosphere to the nitrogen gas atmosphere at 700° C. after reducing the temperature. Except for these, the heat treatment was carried out under the same conditions as were described in Example 3.

With respect to the surface of the silicon wafer after the heat treatment, the surface concavo-convex image and the surface roughness Rms of the 3 μm×3 μm area were measured by means of AFM.

FIG. 6 shows the surface unevenness image of the silicon wafer by AFM observation.

### Comparative Example 3

The inside of the furnace was changed from the nitrogen gas atmosphere to the argon gas atmosphere and the heat treatment was carried out at 700° C. before raising the temperature. The inside of the furnace was changed from the argon gas atmosphere to the nitrogen gas atmosphere at 700° C. after reducing the temperature. Except for these, the heat treatment was carried out under the same conditions as were described in Example 3.

With respect to the surface of the silicon wafer after the heat treatment, the surface concavo-convex image and the surface roughness Rms of the 3 μm×3 μm area were measured by means of AFM.

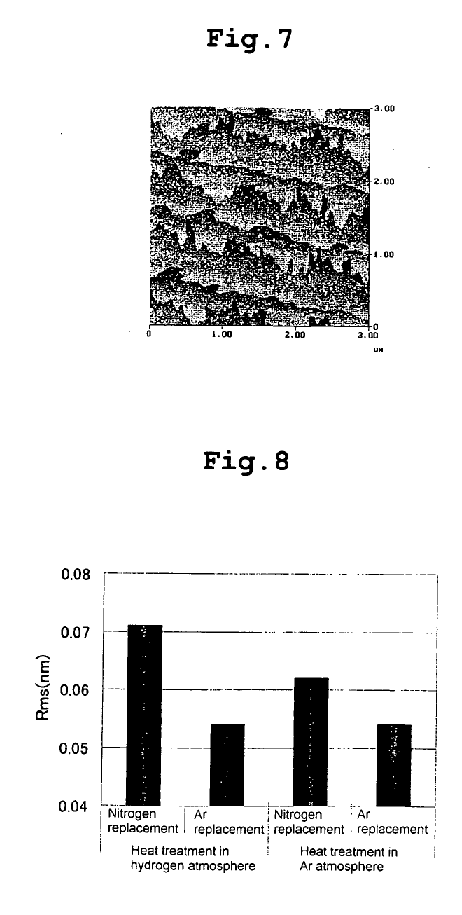

FIG. 7 shows the surface unevenness image of the silicon wafer by AFM observation.

As can be seen from the photographs of FIGS. 4-7, in the heat treatment in the hydrogen gas atmosphere, the surface step terrace structure considerably varied with the replacing gas. The step line became wave-like in the case where the replacing gas was argon (Example 3), and the step line was sawtooth-like in the case where the replacing gas was nitrogen (Comparative Example 2).

Further, in the heat treatment under the argon gas atmosphere, the step line became wave-like in the case where the replacing gas was argon (always argon) (Example 4), and the step terrace structure where the step line had a shape intermediate the sawtooth-like shape and the wave-like shape was observed in the case of nitrogen (Comparative Example 3).

Further, FIG. 8 shows a graph of a comparison of the surface roughnesses Rms measured from the photographs of FIGS. 4-7.

In the heat treatment under the hydrogen gas atmosphere, the surface roughness Rms was 0.071 nm in the case of the nitrogen gas replacement (Comparative Example 2), and it was 0.054 nm in the case of the argon gas replacement (Example 3). Further, in the heat treatment under the argon gas atmosphere, it was 0.062 nm in the case of the nitrogen gas replacement (Comparative Example 3), and it was 0.054 nm in the argon gas replacement (always argon gas) (Example 4).

Since the shape of the step terrace changes with the replacing gas, the surface roughnesses also differ. It was found that argon was used for the replacing gas at a predetermined temperature to thereby reduce the surface roughness Rms to 0.06 nm or less.

In addition, although the temperature at the time of replacing the atmosphere inside the furnace at the time of reducing the temperature was 700° C. in the above-mentioned Examples and Comparative Examples, it was found that an equivalent effect is acquired even when it was 500° C.

### Example 5

Under the same conditions as were described in Example 3, the temperature was reduced after carrying out the heat-treatment. The inside of the furnace was changed from the hydrogen gas atmosphere to the argon gas atmosphere at 700° C.

When the wafer boat was removed from the furnace after completion of the replacement, the outflow gas flow velocity at the opening of the furnace bottom was changed, and each surface roughness Rms of the silicon wafer removed from the furnace at each gas speed was measured.

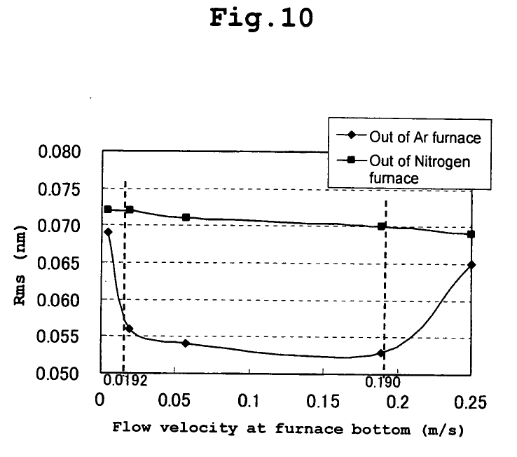

FIG. 10 shows in graph a relationship between the outflow gas flow velocity at the opening of the furnace bottom and the surface roughness of the silicon wafer.

In addition, it appears that differences from the values of surface roughnesses shown in the above-mentioned Examples 1-4 only depend on the individual specificity of the wafer.

### Comparative Example 4

After the heat treatment was carried out under the same conditions as were described in Example 3, the temperature was reduced and the inside of the furnace was changed from the hydrogen gas atmosphere to the nitrogen gas atmosphere at 700° C.

When the wafer boat was removed from the furnace after completion of the replacement, the outflow gas flow velocity at the opening of the furnace bottom was changed, and each surface roughness Rms of the silicon wafer removed from the furnace at each gas speed was measured.

FIG. 10 shows in graph a relationship between the outflow gas flow velocity at the opening of the furnace bottom and the surface roughness of the silicon wafer together with Example 5.

From the graph as shown in FIG. 10, it has been found that it is preferable to continue introducing argon gas into the furnace until the silicon wafer is removed from the furnace, and that as for the atmosphere in the furnace at the time of removing the silicon wafer from the furnace, the flatness of the surface of the silicon wafer is maintained better by argon gas (Example 5) than by nitrogen gas (Comparative Example 4).

In the above-mentioned Examples and Comparative Examples, in order to show more clearly the effect of reducing the surface roughness and the difference of the surface structure, the silicon wafer sliced at a small OFF angle of 0.03° was used, however the present invention is not limited to the magnitude of the OFF angle, and the effect of reducing the surface roughness of the silicon wafer can be obtained even when the OFF angle is increased.

What is claimed is:

1. A heat treatment method for a silicon wafer in which a step terrace structure is formed on a surface of the silicon wafer, wherein after the silicon wafer is heat treated at 1,100° C. or more in a heat treatment furnace in a reducing gas or inert gas atmosphere, the atmosphere in the furnace is arranged to be of argon gas at a temperature of 500° C. or more in the furnace when reducing the temperature and argon gas continues to be introduced into the furnace until the silicon wafer is removed from the furnace, so that the step terrace structure on the surface of said silicon wafer may be maintained and a root mean square roughness Rms per 3 μm×3 μm may be 0.06 nm or less.

2. The heat treatment method for the silicon wafer according to claim 1, wherein at least argon gas continues to be introduced into the furnace until the whole wafer-placing unit of a wafer boat having thereon said silicon wafer comes out of the furnace.

3. The heat treatment method for the silicon wafer according to claim 2, wherein said whole wafer boat is surrounded by argon gas which flows from the inside of the furnace when removing said wafer boat from the furnace.

4. The heat treatment method for the silicon wafer according to claim 3, wherein a flow velocity of argon gas which flows out of an opening of a furnace bottom is between 0.0192 m/s and 0.190 m/s (inclusive) when said wafer boat is removed from the furnace bottom.
